(19) United States
(12) Patent Application Publication
(10) Pub. No.: US 2016/0003782 A1
(43) Pub. Date: Jan. 7, 2016

(54) SYSTEM FOR PREDICTION AND PREVENTION OF ELECTRIC TRANSFORMER FAILURES

(71) Applicant: MASTINC, New York, NY (US)

(72) Inventors: Brian VON HERZEN, Minden, NV (US); Steven VAN FLEET, Lagrangeville, NY (US)

(21) Appl. No.: 14/790,755

(22) Filed: Jul. 2, 2015

Related U.S. Application Data
(60) Provisional application No. 62/020,561, filed on Jul. 3, 2014.

(51) Int. Cl. G01N 29/24; G01R 31/02; G01M 11/00

(52) U.S. Cl. CPC G01N 29/2418; G01M 11/30; G01R 31/027

(57) ABSTRACT

The present application relates to systems for detection of partial discharges in a power transformer. In embodiments, the systems utilize fiber optic acoustic sensors to monitor the pressure waves associated with partial discharges and localize the discharges using appropriate measurement and analysis software.

### FIELD OF THE INVENTION

The present application relates to systems for detection of partial discharges in a power transformer. In embodiments, the systems utilize fiber optic acoustic sensors to monitor the pressure waves associated with partial discharges and localize the discharges using appropriate measurement and analysis software.

### BACKGROUND OF THE INVENTION

Detection of partial discharges in power transformers is an indicator of degradation and potentially imminent failure. Partial discharges are caused by electrical conduction in the insulating oil of a transformer, and are characterized by spikes in the electric and magnetic fields. Early detection of partial discharges can significantly reduce repair costs and loss of revenue from outages and other issues. With early detection of partial discharges and identification of degraded transformers, a utility can proactively repair aging transformers before widespread disruptions or outages occur.

Chemical measurement of the composition of transformer insulating oil can provide dissolved gas analysis (DGA) and other measurements for monitoring oil, oxidation products, and hydrocarbons. These approaches, however, provide information on transformer failure after they have failed (i.e., after partial discharges have already occurred). Partial discharge detection via electrical (UHF) and simple acoustic measurements are also possible. However, there is a need for an early detection method to predict and/or detect partial discharge, which allows for specific localization of the discharge.

### SUMMARY OF PREFERRED EMBODIMENTS

The present application provides systems and methods that meet the needs identified above.

In embodiments, systems for detection of a partial discharge in a power transformer are provided. Such system suitably comprise a control module, positioned outside the power transformer, a data acquisition module, positioned outside the power transformer and a fiber optic acoustic sensor coupled to the control module and the data acquisition module. The fiber optic acoustic sensor suitably comprises an optical fiber (and suitably at least 3 optical fibers) at least partially disposed within the power transformer and one or more mirrors configured to phase rotate an optical signal of the optical fiber by 90°±1°, the one or more mirrors positioned outside the power transformer.

In embodiments, the systems further comprise a dissolvable coating surrounding the optical fiber.

In embodiments, the optical fiber comprises a coiled optical fiber. For example, the coiled optical fiber is wound around a mandrel having a Young's modulus of about 0.01 GPa to about 1.0 GPa and a dielectric strength of about 40 MV/m to about 200 MV/m. In embodiments, the coiled optical fiber is wound around a mandrel comprising Teflon.

In additional embodiments, the systems further comprise a reference optical fiber disposed outside the power transformer.

Suitably, a laser of the control module is a pulsed laser or a continuous wave laser.

Also provided are systems for detection of a partial discharge in a power transformer, comprising a control module, positioned outside the power transformer, a data acquisition module, positioned outside the power transformer, and a fiber optic acoustic sensor coupled to the control module and the data acquisition module. The fiber optic acoustic sensor suitably comprises an interferometer comprising a coiled optical fiber (suitably at least 3 optical fibers) at least partially disposed within the power transformer, a reference optical fiber, a sensor mirror and a reference mirror.

As described herein, the systems suitably further comprise a dissolvable coating surrounding the coiled optical fiber. In embodiments, the coiled optical fiber is wound around a mandrel having a Young's modulus of about 0.01 GPa to about 1.0 GPa and a dielectric strength of about 40 MV/m to about 200 MV/m, and suitably the coiled optical fiber is wound around a mandrel comprising Teflon.

In additional embodiments, a laser of the control module is a pulsed laser or a continuous wave laser.

In further embodiments, systems for detection of a partial discharge in a power transformer are provided comprising a control module, positioned outside the power transformer a data acquisition module, positioned outside the power transformer and a fiber optic acoustic sensor coupled to the control module and the data acquisition module, the fiber optic acoustic sensor comprising an optical fiber at least partially disposed within the power transformer, the optical fiber comprising a fiber Bragg grating.

In embodiments, the optical fiber comprises a polarization-preserving fiber. In suitable embodiments, the optical fiber comprises two or more fiber Bragg gratings, suitably four fiber Bragg gratings.

Suitably a reference optical fiber disposed outside the power transformer, and suitably the reference optical fiber comprises two or more fiber Bragg gratings.

In additional embodiments, the systems further comprise a dissolvable coating surrounding the optical fiber.

In embodiments, a laser of the control module is a pulsed laser or a continuous wave laser.

In additional embodiments, the optical fiber is operated in a dense wavelength division multiplexing mode, and suitably, the optical fiber is operated using Rayleigh scattering.

Also provided are methods of detecting and localizing a partial discharge in a power transformer. The methods suitably comprise providing the system as described herein for detection of a partial discharge in a power transformer, triggering the fiber optic acoustic sensor to gather acoustic data from the partial discharge, transmitting the acoustic data to the data acquisition module and calculating the location of the partial discharge within the power transformer.

Further embodiments, features, and advantages of the embodiments, as well as the structure and operation of the various embodiments, are described in detail below with reference to accompanying drawings.

### BRIEF DESCRIPTION OF THE FIGURES

FIG. 1 shows a cross-section of a simplified power transformer.

FIG. 2 shows a system for detection of a partial discharge in a power transformer, comprising mirrors, as described herein.

FIG. 3 shows a further system for detection of a partial discharge in a power transformer, as described herein.

FIG. 4 shows a system for detection of a partial discharge in a power transformer, comprising fiber Bragg grating(s), as described herein.

FIG. 5 shows a further system for detection of a partial discharge in a power transformer, comprising fiber Bragg grating(s), as described herein.

FIG. 6 shows a cross-section of a simplified power transformer, including the addition of a system for detection of a partial discharge, as described herein.

### DETAILED DESCRIPTION OF PREFERRED EMBODIMENTS

It should be appreciated that the particular implementations shown and described herein are examples and are not intended to otherwise limit the scope of the application in any way.

The published patents, patent applications, websites, company names, and scientific literature referred to herein are hereby incorporated by reference in their entireties to the same extent as if each was specifically and individually indicated to be incorporated by reference. Any conflict between any reference cited herein and the specific teachings of this specification shall be resolved in favor of the latter. Likewise, any conflict between an art-understood definition of a word or phrase and a definition of the word or phrase as specifically taught in this specification shall be resolved in favor of the latter.

As used in this specification, the singular forms “a,” “an” and “the” specifically also encompass the plural forms of the terms to which they refer, unless the content clearly dictates otherwise. The term “about” is used herein to mean approximately, in the region of, roughly, or around. When the term “about” is used in conjunction with a numerical value or range, it modifies that value or range by extending the boundaries above and below the numerical values set forth. In general, the term “about” is used herein to modify a numerical value above and below the stated value by a variance of 20%.

Technical and scientific terms used herein have the meaning commonly understood by one of skill in the art to which the present application pertains, unless otherwise defined. Reference is made herein to various methodologies and materials known to those of ordinary skill in the art.

### Systems for Detection of Partial Discharges

In embodiments, systems for detection a partial discharge in a power transformer are provided.

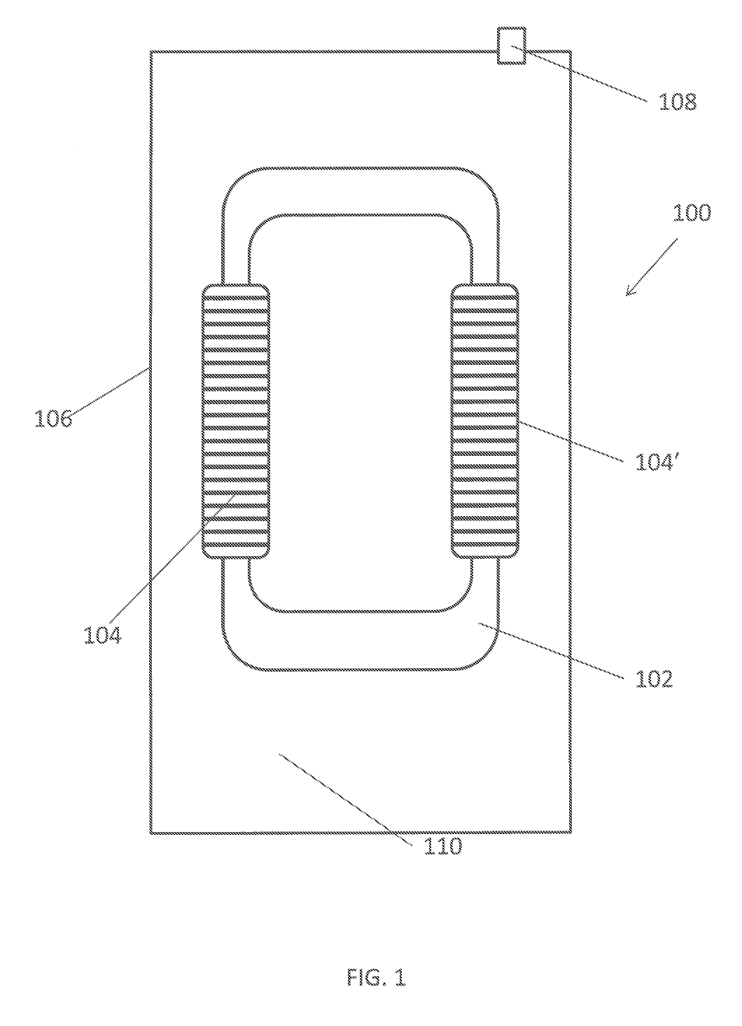

FIG. 1 provides a figure of a cross-section of a simplified power transformer. The transformer shown is a diagram of a single phase, core-type transformer. Those skilled in the art will readily recognize other core forms and shell forms can be readily used in combination with the various systems and methods described herein.

As shown in FIG. 1, transformer 100 suitably comprises a transformer core 102, two windings, suitably a primary winding 104 and a secondary winding 104′. Also shown in FIG. 1 is transformer case 106 enclosing the core and windings, as well as transformer oil 110 suitably surrounding the windings and core, and within the casing. Also shown is access port 108 that allows access to the inside of the transformer.

As described herein, provided are various systems for detection of a partial discharge in a power transformer.

As used herein, a “partial discharge” refers to a localized dielectric breakdown of a small portion of a solid or fluid electrical insulation system in a power transformer under high voltage stress.

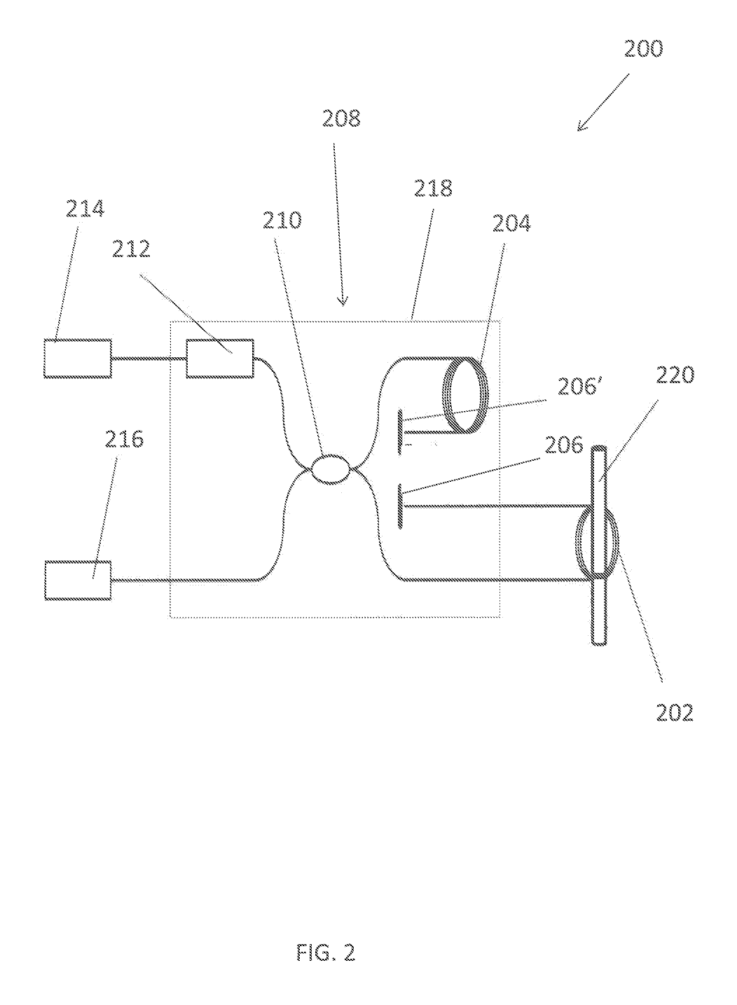

In embodiments, as shown in FIG. 2, a system 200 for detection of a partial discharge is provided. Suitably, the system comprises a control module 214 positioned outside of a power transformer that is being monitored. System 200 also further comprises a data acquisition module 216, also positioned outside the power transformer. Exemplary components of control module 214 include one or more lasers, various electronic control units, etc. Exemplary components of data acquisition module 216 include various computational systems, storage systems, etc., including for example an oscilloscope and connected computer to capture the information provided by the sensors, as well as suitable software processing systems.

System 200 also comprises a fiber optic acoustic sensor 208 coupled to control module 214 and data acquisition module 216. As used herein, “coupled,” when referring to the interaction between fiber optic acoustic sensor 208, control module 214 and data acquisition module 216, is used to indicate that the three components (208, 214 and 216) of the system are able to communicate with each other. Such coupling can either be via direct, electrical connection (i.e., a direct wiring) or can occur wirelessly through various telemetry methods, including radio, ultrasonic, or infrared systems, etc.

Fiber optic acoustic sensor 208 can be, as shown in FIG. 2, within an enclosure 218. Suitably, fiber optic acoustic sensor 208 comprises an optical fiber 202, at least partially disposed within the power transformer, and one or more mirrors 206/206′. Suitably, mirror 206/206′ is configured to phase rotate an optical signal of the optical fiber 202 by 90°±1°. Suitably, the one or more mirrors 206/206′ are positioned outside the power transformer. Suitably, the one or more mirrors 206/206′ are Faraday mirrors. As used herein, a “Faraday mirror” refers to a phase conjugate mirror which creates a phase delay of 90°.

As used herein, “optical fiber” refers to a flexible, transparent fiber made of high quality extruded glass (e.g., silica or glass material) or plastic, functioning to transmit light between the two ends of the fiber. The optical fibers described herein allow for the measurement of acoustic signals via measuring the changes in the intensity, phase, polarization, wavelength, or transit time of light in the fiber due to strain in the fiber caused by an impinging acoustic wave from a partial discharge.

Suitable, the optical fibers for use in the embodiments described herein are single mode optical fibers, suitably comprising a glass/silica core and a cladding surrounding the core. In exemplary embodiments, the core is a doped silica core, and the cladding is undoped. Exemplary dopants include, but are not limited to, germania (GeO₂) (germanosilicate fibers), phosphorus pentoxide (P₂O₅) (phosphosilicate), and alumina (Al₂O₃) (aluminosilicate). However, in additional embodiments, the cladding can also be doped (e.g., fluorine or boron oxide doping), or the core can be undoped and the cladding doped or undoped. Suitable additional embodiments of the fiber optic cables include a core comprising a polymeric material. Suitably, the cladding of the optical fiber is selected so as to be thin in comparison to the overall diameter of the optical fiber.

Additional, optional components of fiber optic sensor 208 include a coupler 210 and an isolator 212 (a one-way device to prevent laser feedback noise, which can occur if light is reflected back into a laser of the system). In embodiments, the system 200 further comprises a reference optical fiber 204 disposed outside the power transformer.

In suitable embodiments, the optical fibers for use in the systems comprise a coiled optical fiber. As used herein “coiled” refers to a shape of the optical fiber where it is arranged or wound around in a joined sequence of concentric circles or rings. Suitably, the coiled optical fibers are prepared by winding the fibers around on the order of 10-100 loops.

Suitably, in systems described herein, coiled optical fiber is wound around a mandrel 220, as shown in FIG. 2. As used herein, “mandrel” refers to a substantially cylindrically shaped object, around which an optical fiber can readily be wound, so as to alter the path of the light travelling in the fiber. Other suitable shapes, including rods, bars, cones, rectangular shapes, etc, as well as irregular shaped mandrels can also be used.

Suitably, the coiled optical fiber is wound around a mandrel having a Young's modulus of about 0.01 GPa to about 1.0 GPa and a dielectric strength of about 40 MV/m to about 200 MV/m. For example, in embodiments, the coiled optical fiber is wound around a mandrel having a Young's modulus of about 0.1 GPa to about 1.0 GP, about 0.3 GPa to about 0.7 GPa, or about 0.1 GPa, about 0.2 GPa, about 0.3 GPa, about 0.4 GPa, about 0.5 GPa, about 0.6 GPa, about 0.7 GPa, about 0.8 GPa, about 0.9 GPa, or about 1.0 GPa. In embodiments, the coiled optical fiber is wound around a mandrel having a dielectric strength of about 40 MV/m to about 180 MV/m, about 60 MV/m to about 173 MV/m, or about 60 MV/m, about 70 MV/m, about 80 MV/m, about 90 MV/m, about 100 MV/m, about 110 MV/m, about 120 MV/m, about 130 MV/m, about 140 MV/m, about 150 MV/m, about 160 MV/m, about 170 MV/m, or about 180 MV/m.

Exemplary materials for use in constructing mandrel 220, include for example, rubber, Teflon, low density polyethylene, high density polyethylene and polypropylene, as well as composites of such materials and others known in the art having the desired Young's modulus and dielectric strength described herein. Suitably mandrel 220 comprises Teflon. Selection of Teflon as the mandrel material also reduces the mismatch in impedance between the oil and the mandrel, thereby improving efficiency of the sensors described herein.

The optical fibers for use herein suitable have a fiber diameter (which includes the core and the cladding) of a few microns to up to about 125 microns. In exemplary embodiments, the diameter of the optical fibers are on the order of 10 s of microns, suitably about 10 μm to about 125 μm, more suitably about 40 μm to about 100 μm, or about 40 μm, about 50 μm, about 60 μm, about 70 μm, about 80 μm, about 90 μm, or about 100 μm. As one of ordinary skill will readily understand, the use of smaller diameter optical fibers allows for the preparation of coiled optical fibers that have a very small bend radius, enabling a tighter coil (on the order of 100 mm or less, suitably 10 mm or less) and thus a higher frequency response.

Exemplary optical fibers for use in the embodiments described herein include, for example, a single mode fiber having a diameter of 80 μm (e.g., SM800G80; SM 1250G80; THORLABS, Newton, N.J.). Fibers having a diameter of 80 μm offer significant improvement in the frequency response over those having a diameter of 125 μm or higher, and thus improved detection of partial discharges as described herein.

In suitable embodiments, the systems further comprise a dissolvable jacket surrounding the optical fiber (i.e. a coating surrounding the fiber—this can be a gel, solid or semi-solid coating). The use of a dissolvable jacket provides a mechanism for effectively “self-cleaning” the optical fiber after placement in a transformer oil. During handling and installation, dirt, debris, fingerprints, etc., can find their way on to the jacket of the optical fiber, providing potential sites at which a partial discharge can occur. In addition, nicks or cuts can also occur to the jacket, creating defects. Utilizing a dissolvable jacket as described herein provides a mechanism such that, when placed in transformer oil, the jacket dissolves (either partially or completely) so as to effectively clean any debris from the surface of the fiber, and also to removing any defective jacket, revealing the protected fiber underneath, that is now in direct contact with the transformer oil. Exemplary dissolvable jackets suitable comprise a hydrocarbon that is solid at room temperature (and up to normal air temperature, e.g., 80-100° C.), but dissolves in transformer oil and/or at an elevated temperature, but such that the dissolution does not negatively impact the composition of the transformer oil. Exemplary dissolvable jackets suitably comprise solid paraffin wax, for example. Additional dissolvable jackets can comprise for example, lipids.

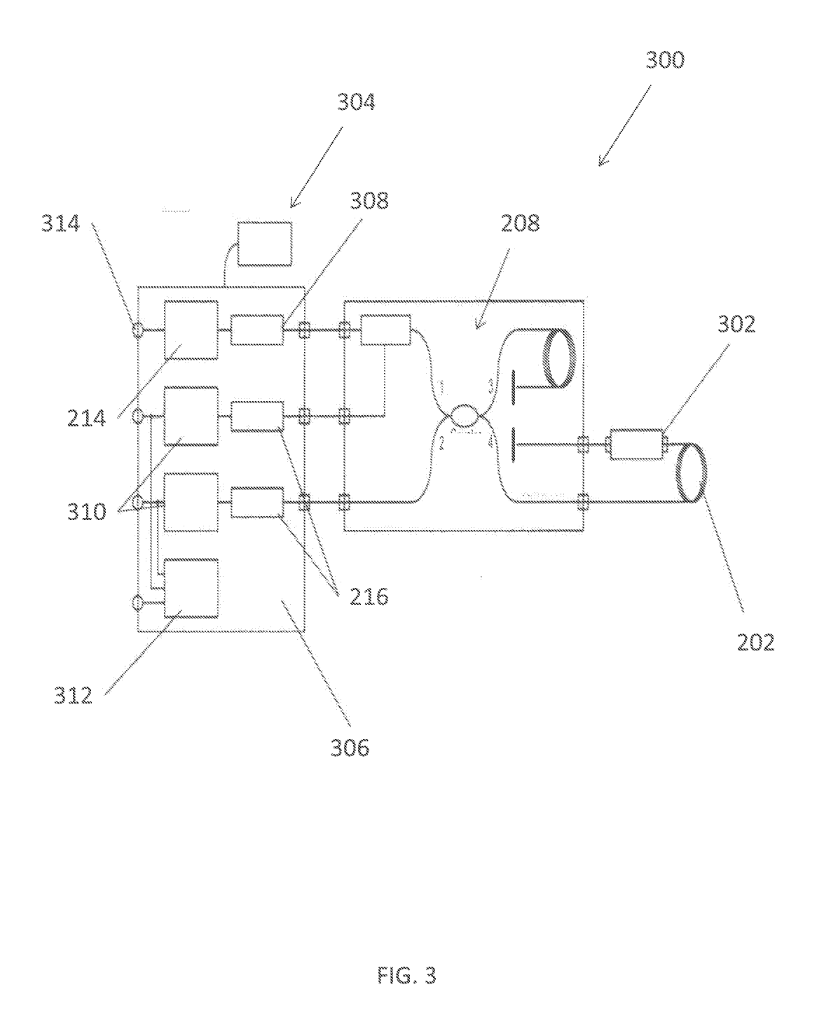

FIG. 3 shows a further embodiment of a system 300 for detection of a partial discharge in a transformer. System 300 shows the elements of fiber optic sensor 208, coupled to control module 214 and two detector modules 216. As shown in FIG. 3, control module 214 and detector module 216 are suitably contained within an assembly 306, which provides stability to the modules, as well as protection from environmental factors when the systems described herein are employed in the field (e.g., a metal or other suitable enclosure). Assembly 306 can also further include additional elements that assist in the operation of the system 300, including for example one or more detector amplifiers 310, as well as appropriate signal circuitry 312, connectors 314 (e.g., (Bayonet Neill-Concelman, BNC) connectors) and power supplies 304 (e.g., battery packs). In embodiments, a delay line 302 is also further added to the optical fiber 202.

In further embodiments, the systems provided herein include a laser 308 of the control module 214, included within assembly 306 that also contains the detector module 216 and control module 214. In embodiments, laser 308 of the control module is a pulsed laser or a continuous wave laser. Exemplary lasers for use in the systems provided herein include, for example, a single mode fiber coupled laser diode, 2 mW @1300 or a wavelength stabilized single mode fiber coupled laser diode, 2 mW @1300 (available from QPhotonics, LLC, Ann Arbor, Mich.).

TABLE 1
Examplary Laser Specifications
Test conditions: temperature 25° C.

| Parameter | Symbol | Min | Typ | Max | Unit |
|---|---|---|---|---|---|
| Optical power from pigtail | P₁ | 1.5 | 2 | | mW |
| Wavelength | λ₀ | 1270 | 1300 | 1330 | nm |
| Residual spectral | | | 2 | 5 | % |
| modulation depth | | | | | |
| (rippies) | | | | | |
| Spectral linewidth (FWHM) | Δλ | 30 | 40 | | nm |
| Forward current | I_{f} | | 250 | 300 | mA |
| Forward voltage | V_{f} | | 1.6 | 2.0 | |
| Secondary coherence | — | | −40 | −30 | dB |
| subpeaks | | | | | |
| TEC current | I_{TEC} | | | 1.5 | A |
| TEC voltage | V_{TEC} | | | 3.5 | V |
| Storage temperature | T_{stg} | −55 | | 85 | ° C. |
| Operating case temperature | Tₑ | 0 | | 65 | ° C. |

In further embodiments, the systems described herein comprise at least 2 optical fibers, more suitably, at least 3 optical fibers, at least 4 optical fibers, at least 5 optical fibers, at least 10 optical fibers, at least 20 optical fibers, at least 50 optical fibers, at least 100 optical fibers, at least 500 optical fibers, at least 1000 optical fibers, or 10-1000 optical fibers, 10-100 optical fibers, 10-50 optical fibers, 1-50 optical fibers, 1-20 optical fibers, or 1-10 optical fibers, or any values or ranges within these values.

Also provided are additional systems for detection of a partial discharge in a power transformer, also represented schematically in FIGS. 2 and 3. Suitably, such systems comprise a control module 214, positioned outside the power transformer, a data acquisition module 216, positioned outside the power transformer; and a fiber optic acoustic sensor 208 coupled to the control module and the data acquisition module. In suitable embodiments, the fiber optic acoustic sensor 208 comprises an interferometer comprising a coiled optical fiber 202 at least partially disposed within the power transformer, a reference optical fiber 204, a sensor mirror 206 and a reference mirror 206′.

Fiber optic acoustic sensor 208 can be, as shown in FIG. 2, within an enclosure 218. Suitably, sensor mirror 206 and reference mirror 206′ are configured to phase rotate an optical signal of the optical fiber 202 by about 90°. Suitably, the mirrors 206/206′ are positioned outside the power transformer. Suitably, the one or more mirrors 206/206′ are Faraday mirrors

Additional, components of fiber optic sensor 208 include a coupler 210 and an isolator 212 (a one-way device to prevent laser feedback noise, which can occur if light is reflected back into the laser). In embodiments, the system 200 further comprises a reference optical fiber 204 disposed outside the power transformer.

In suitable embodiments, the optical fiber comprises a coiled optical fiber. Suitably, in systems described herein, coiled optical fiber is wound around a mandrel 220, as shown in FIG. 2.

Suitably, the coiled optical fiber is wound around a mandrel having a Young's modulus of about 0.01 GPa to about 1.0 GPa and a dielectric strength of about 40 MV/m to about 200 MV/m, as described herein. Exemplary materials for use in constructing mandrel 220, include for example, rubber, Teflon, low density polyethylene, high density polyethylene and polypropylene, as well as composites of such materials and others know in the art having the desired Young's modulus and dielectric strength described herein. Suitably mandrel 220 comprises Teflon.

In suitably embodiments, as described herein, the systems further comprise a dissolvable jacket surrounding the optical fiber.

In further embodiments, the systems described herein comprise at least 2 optical fibers, more suitably, at least 3 optical fibers, at least 4 optical fibers, at least 5 optical fibers, at least 10 optical fibers, at least 20 optical fibers, at least 50 optical fibers, at least 100 optical fibers, at least 500 optical fibers, at least 1000 optical fibers, or 10-1000 optical fibers, or 10-100 optical fibers, or 10-50 optical fibers, or 1-50 optical fibers, or 1-20 optical fibers, or 1-10 optical fibers, or any values or ranges within these values.

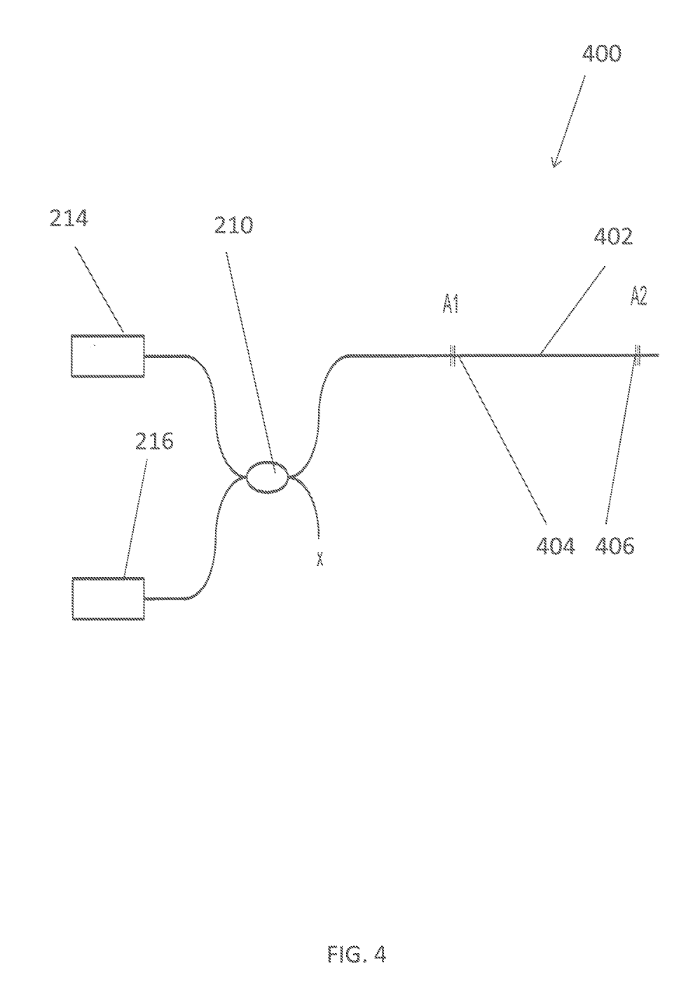

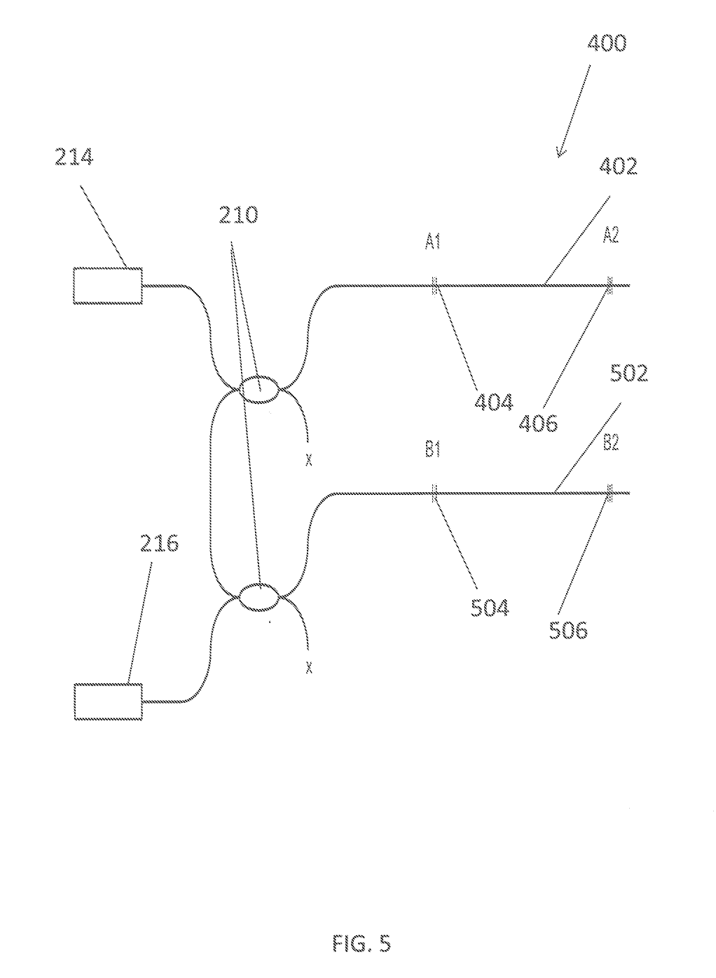

Also provided herein are systems for detection of a partial discharge in a power transformer as shown in FIGS. 4-5. System 400 for detection of a partial discharge in a power transformer suitably comprises control module 214, positioned outside the power transformer, data acquisition module 216, positioned outside the power transformer, and a fiber optic acoustic sensor 402 coupled to the control module and the data acquisition module. Suitably, in system 400, the fiber optic acoustic sensor comprises an optical fiber at least partially disposed within the power transformer, the optical fiber comprising a fiber Bragg grating (404/406).

As used herein, a “fiber Bragg grating” refers to a distributed Bragg reflector constructed in an optical fiber that reflects particular wavelengths of light and transmits all others. It is achieved by creating a periodic variation in the refractive index of the fiber core, which generates a wavelength specific dielectric mirror. A fiber Bragg grating is used in embodiments described herein as an inline optical filter to block certain wavelengths, or as a wavelength-specific reflector.

Suitably, at regular intervals along the optical fiber, fiber Bragg gratings comprising periodic variations in the refractive index of the fiber core are introduced which act as notch filters to reflect a narrow wavelength band. Light travelling down the fiber interferes with these periodic variations in refractive index. Wavelengths in narrow bands are reflected at those respective segments. One grating has a spatial frequency and acts as one notch filter. A second grating has a second spatial frequency and acts as a second notch filter. A third or more grating(s) have a third and more frequency(ies) and act as a third or more notch filter(s).

Several variables affect reflectance of fiber Bragg gratings. One is temperature, which varies as a low-frequency signal on the order of minutes/hours/days. Acoustic signals also affect reflectance, but on timescales of milliseconds to microseconds. Thus, the two signals can be separated using a single fiber for both temperature and acoustics due to the bandwidth separation of those elements of the returned signal.

In embodiments, to further resolve acoustic signals of partial discharges at different locations using optical fibers comprising fiber Bragg gratings, dense wavelength division multiplexing (DWDM) is utilized to send multiple wavelengths (frequencies) of light down the fibers, and the fiber Bragg gratings reflect different wavelengths at different segments of the fiber. For example, with three frequencies of light to be used, the fiber Bragg gratings constructed with the first section target frequency 1, second section is constructed to interfere with frequency 2 and third section is scored to constructively interfere with frequency 3. By using this method and by induction, the system can use as many frequencies as needed to avoid interference (for example, after using frequency 3, the system could start again at frequency 1 if there is no interference with the previous fiber segment reflecting frequency 1).

In suitable embodiments, the optical fiber comprises a polarization-preserving optical fiber, or polarization-maintaining optical fiber which is a single-mode optical fiber in which linearly polarized light, if properly launched into the fiber, maintains a linear polarization during propagation, exiting the fiber in a specific linear polarization state. There is little or no cross-coupling of optical power between the two polarization modes. Exemplary polarization-preserving optical fibers include Polarization-maintaining and Absorption reducing fibers from Fujikura (Tokyo, Japan). Exemplary characteristics of such fibers are provided in Table 2.

TABLE 2
Specifications for UV/UV PANDA fibers

| | | | | | Cross- | | | |
|---|---|---|---|---|---|---|---|---|
| | | | Aff. | Beat | talk | | Coating | Coating |
| | λₒ | MFO | Max. | length | Max. | λ_{c} | material | diameter |
| | μm | +/−0.5 μm | dB/km | mm | dB/100 m | μm | — | μm |
| SM85-PS-U40D | 0.85 | 5.5 | 3.0 | 1.0-2.0 | −30 | 0.65-0.80 | UV/UV | 400 ± 15 |
| SM85-PS-U25D | | | | | | | | 245 ± 15 |
| SM98-PS-U40D | 0.98 | 6.6 | 2.5 | 1.5-2.7 | | 0.87-0.95 | | 400 ± 15 |
| SM98-PS-U25D | | | | | | | | 245 ± 15 |
| SM13-PS-U40D | 1.3 | 0.0 | 1.0 | 2.6-4.0 | | 1.13-1.27 | | 400 ± 15 |
| SM13-PS-U25D | | | | | | | | 245 ± 15 |
| SM14-PS-U40D | 1.40-1.49 | 9.8 | 1.0 | 2.8-4.7 | | 1.26-1.38 | | 400 ± 15 |
| SM14-PS-U25D | | | | | | | | 245 ± 15 |
| SM15-PS-U40D | 1.55 | 10.5 | 0.5 | 3.0-5.0 | | 1.30-1.44 | | 400 ± 15 |
| SM15-PS-U25D | | | | | | | | 245 ± 15 |

In exemplary embodiments, as shown in FIG. 4, the optical fiber comprises two or more fiber Bragg gratings (e.g., 404/A1 and 406/A2). In further embodiments, the systems comprise optical fibers comprising four fiber Bragg gratings (e.g., FIG. 5, 404/A1, 406/A2, 504/B1 and 506/B2).

In embodiments utilizing two fiber Bragg gratings, interference between the reflections from the two mirrors A1 and A2 is measured. The sensing region is the section of optical fiber between A1 and A2, since a disturbance there will modulate the path difference, while a disturbance on the lead-in section of fiber will not create a changing path difference. In other words, this configuration achieves an insensitive lead-in fiber. Suitably the path difference for the two reflections (i.e. twice the optical distance between the two fiber Bragg gratings) is less than the coherence length of a laser that is utilized.

Suitably, the system as shown in FIG. 5 comprises a reference optical fiber 502. This reference optical fiber can be disposed inside or outside of the power transformer, but is suitably disposed outside the power transformer to reduce electrical interference in the fiber. As shown in FIG. 5, the reference optical fiber 502 suitably comprises two or more fiber Bragg gratings (e.g., 504/B1 and 506/B2).

In the embodiment described in FIG. 5, light reflected back from fiber optic acoustic sensor 402 does not go directly to data acquisition module 216, but is first reflected from the two fiber Bragg gratings (504/B1 and 506/B2) in reference optical fiber 502. Data acquisition module 216 sees four beams that have experienced different paths, i.e. that have reflected from different combinations of fiber Bragg gratings:

path (1), fiber Bragg gratings A1 & B1;

path (2), fiber Bragg gratings A2 & B2;

path (3), fiber Bragg gratings A1 & B2; and

path (4), fiber Bragg gratings A2 & B1.

Assuming the laser has a short coherence length, paths (1) and (2) have very different lengths from the other two paths and from each other, and so do not interfere, but just appear as direct current (d.c.) light. But paths (3) and (4) have nominally the same path lengths from the laser to the data acquisition module 216 and so will be coherent with each other and will interfere. Since path (4) experiences the sensing zone (between A1 and A2) but path (3) does not, the interference will produce a changing detector intensity as the sensor path is disturbed.

It should be noted that fiber optic acoustic sensor 402 and reference optical fiber 502 can be switched, and the system still function as described herein.

The system 400 described herein and shown in FIG. 5, allows for a very long sensing zone (for high sensitivity) even if the laser has a short coherence length, as the difference between paths (3) and (4) is generally less than a coherence length. Exemplary lasers for use in such systems (e.g., QFLD-1300-2SM) have a line width of 0.01 nm, which corresponds to a coherence length of about 16 cm in fiber, i.e., much less than the length of sensing fiber needed for adequate sensitivity (generally about 20 meters round-trip path in a 10-meter fiber). An additional exemplary laser for use in such systems (QFBGLD-1300-2) provides a very narrow width of 10 MHz, corresponding to a long coherence length of about 20 meters in fiber.

As described herein, in suitable embodiments a dissolvable coating surrounds the optical fiber. Additional, components of fiber optic sensor 402 include a coupler 210 and can include an isolator 212 (see FIG. 2). In embodiments, the control module comprises a laser, which can be a pulsed laser or a continuous wave laser.

In embodiments, the optical fiber of system 400 is operated in a dense wavelength division multiplexing mode. In still further embodiments, the optical fiber of system 400 is operated using Rayleigh scattering.

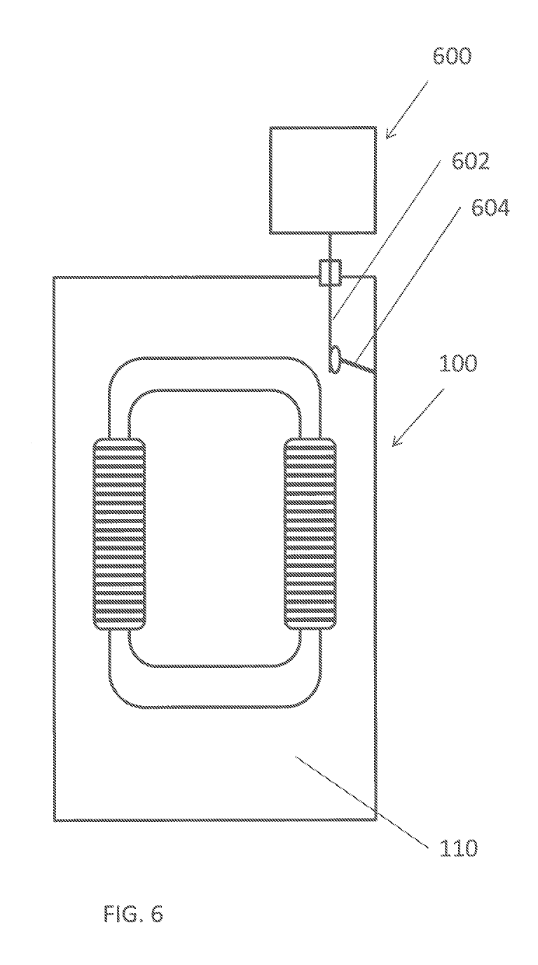

FIG. 6 shows a suitable implementation of the various systems described herein in the field to monitor a power transformer 100. In embodiments, the system 600 is appropriately attached, mounted, placed or otherwise associated with a transformer 100, so as to allow an optical fiber 602 of the fiber optic acoustic sensor to enter the transformer 100, and suitably be positioned within the transformer oil 110. Suitably, the fiber optic acoustic sensor 602 is physically coupled to the transformer case 106 via a coupling device 604. Coupling device 604 allows for physical attachment to the transformer case 106, limiting excessive movement, while still allowing for the sensor to be suspended in the transform oil, and also allows for acoustic isolation from the transformer case 106. Exemplary coupling devices are readily determined by those in the art, and suitably do not interfere with the sensors, and also do not compromise the integrity of the transformer oil or provide sites for additional partial discharges. Coupling devices 604 can include, for example, cable ties, magnets, rubber gaskets, etc.

Also provided are methods of detecting and suitably localizing a partial discharge in a power transformer. In embodiments, the methods comprise providing any one of the systems as described herein for detection of a partial discharge in a power transformer. The fiber optic acoustic sensor is triggered to gather acoustic data from the partial discharge. In embodiments, the triggering can occur from an ultra high frequency (UHF) sensor positioned inside or outside of the transformer, such that when an electromagnetic signal from a partial discharge is detected by the UHF sensor, the sensor triggers to fiber optic acoustic sensor to begin to gather acoustic data from the partial discharge. A circular memory buffer can be stored in the various systems described herein, which, with a UHF trigger can start recording, stop recording and wirelessly transmit telemetry and other data to a controller. After transmitting the acoustic data to the data acquisition module the location of the partial discharge within the power transformer can be calculated.

In suitable embodiments, the systems described herein comprise an array of fiber optic acoustic sensors to detect times of first arrival which can be used with the known locations of the sensors to localize partial discharge events spatially. The exact timing of acoustic first strikes from dozens to thousands of fiber optic acoustic sensors may be utilized.

Methods for calculating the location of a partial discharge are similar to those utilized in detection and localization of seismic events. For example, three or more acoustic sensors are suitable used to measure the arrival time of an acoustic signal in the transformer oil. A 3-D lookup table can be suitable prepared for a sensor configuration in a transformer, so that when an acoustic signal is detected, it is readily mapped to the location using the 3-D lookup table. A lookup table is readily prepared by utilizing a simulation of an acoustic discharge (e.g., an experimentally induced spark gap) in an array, and then determining the time of arrival of the acoustic signal at each of the sensors so as to generate a map for every possible discharge position within the transformer.

As described herein, the fiber optic sensors described herein are suspended in the transformer oil and suitably coupled to the transformer case, but are not acoustically impaired by the transformer case. This allows for an unimpeded path between the sensor and the partial discharge, without interference from the transformer case as the acoustic signal travels through the transformer oil. Also, placing the sensors in the oil provides a direct path to the signal, without having to pass through the transformer casing.

In embodiments which utilize differential Rayleigh scattering in the optical fibers by measuring the temporal deflection of pulsed laser waves travelling in the fiber, it is possible to measure with 100 picosecond (ps) laser pulses, allowing for event localizations on the scale of centimeter. Thus, if a pulse is sent at 1 microsecond (μs) intervals to measure a 500 kHz acoustic signal, a pulse width of 100 ps to 100 ns produces a resolution of 1 cm to 100 m. Time Domain Reflectometry (TDR) techniques can be used for continuous sensing along the fiber of interest. An advantage ofa Rayleigh system is that it is a continuous detection system that is not limited by discrete acoustic sensors.

Further signal processing in the data acquisition module 216 includes a photodiode or a photomultiplier tube (PMT) that detects at nanosecond speeds the reflection magnitude along a Rayleigh fiber or fiber Bragg grating as a function of time/length down fiber as for pulsed laser systems. The nanoscale acoustic signature can be digitized using one or more digital storage oscilloscope channels, which can also provide real time feeds. This allows for a digitally sampling oscilloscope to take an optical signal and transform it for further digital signal processing by a computing system. This signal processing chain for processing said optical signal coming from a fiber can be a Beowulf cluster. At a microsecond timescale the system can take acoustic samples. For frequency multiplexing on the optical fiber sensor a different frequency can be assigned to different lengths of the fiber. For example in 1 meter steps, the 1st meter is optimized for frequency 1, 2nd meter optimized for frequency 2, etc.

The techniques described herein can be applied to various transformers, such as large network/distribution, or transmission transformers. In these scenarios, the systems are suitably installed outside the winding but inside the encapsulating case and oil.

It will be readily apparent to one of ordinary skill in the relevant arts that other suitable modifications and adaptations to the methods and applications described herein can be made without departing from the scope of any of the embodiments.

It is to be understood that while certain embodiments have been illustrated and described herein, the claims are not to be limited to the specific forms or arrangement of parts described and shown. In the specification, there have been disclosed illustrative embodiments and, although specific terms are employed, they are used in a generic and descriptive sense only and not for purposes of limitation. Modifications and variations of the embodiments are possible in light of the above teachings. It is therefore to be understood that the embodiments may be practiced otherwise than as specifically described.

What is claimed is:

1. A system for detection of a partial discharge in a power transformer, comprising:
a) a control module, positioned outside the power transformer;
b) a data acquisition module, positioned outside the power transformer; and
c) a fiber optic acoustic sensor coupled to the control module and the data acquisition module, the fiber optic acoustic sensor comprising:
i. an optical fiber at least partially disposed within the power transformer; and
ii. one or more mirrors configured to phase rotate an optical signal of the optical fiber by 90°±1°, the one or more mirrors positioned outside the power transformer.

2. The system of claim 1, further comprising a dissolvable coating surrounding the optical fiber.

3. The system of claim 1, wherein the optical fiber comprises a coiled optical fiber.

4. The system of claim 3, wherein the coiled optical fiber is wound around a mandrel having a Young's modulus of about 0.01 GPa to about 1.0 GPa and a dielectric strength of about 40 MV/m to about 200 MV/m.

5. The system of claim 3, wherein the coiled optical fiber is wound around a mandrel comprising Teflon.

6. The system of claim 1, further comprising a reference optical fiber disposed outside the power transformer.

7. The system of claim 1, wherein a laser of the control module is a pulsed laser or a continuous wave laser.

8. The system of claim 1, comprising at least 3 optical fibers.

9. A system for detection of a partial discharge in a power transformer, comprising:
a) a control module, positioned outside the power transformer;
b) a data acquisition module, positioned outside the power transformer; and
c) a fiber optic acoustic sensor coupled to the control module and the data acquisition module, the fiber optic acoustic sensor comprising:
i. an interferometer comprising a coiled optical fiber at least partially disposed within the power transformer, a reference optical fiber, a sensor mirror and a reference mirror.

10. The system of claim 9, further comprising a dissolvable coating surrounding the coiled optical fiber.

11. The system of claim 9, wherein the coiled optical fiber is wound around a mandrel having a Young's modulus of about 0.01 GPa to about 1.0 GPa and a dielectric strength of about 40 MV/m to about 200 MV/m.

12. The system of claim 9, wherein the coiled optical fiber is wound around a mandrel comprising Teflon.

13. The system of claim 9, wherein a laser of the control module is a pulsed laser or a continuous wave laser.

14. The system of claim 9, comprising at least 3 optical fibers.

15. A system for detection of a partial discharge in a power transformer, comprising:
a) a control module, positioned outside the power transformer;
b) a data acquisition module, positioned outside the power transformer; and
c) a fiber optic acoustic sensor coupled to the control module and the data acquisition module, the fiber optic acoustic sensor comprising an optical fiber at least partially disposed within the power transformer, the optical fiber comprising a fiber Bragg grating.

16. The system of claim 15, wherein the optical fiber comprises a polarization-preserving fiber.

17. The system of claim 15, wherein the optical fiber comprises two or more fiber Bragg gratings.

18. The system of claim 17, wherein the optical fiber comprises four fiber Bragg gratings.

19. The system of claim 15, further comprising a reference optical fiber disposed outside the power transformer.

20. The system of claim 19, wherein the reference optical fiber comprises two or more fiber Bragg gratings.

21. The system of claim 15, further comprising a dissolvable coating surrounding the optical fiber.

22. The system of claim 15, wherein a laser of the control module is a pulsed laser or a continuous wave laser.

23. The system of claim 15, wherein the optical fiber is operated in a dense wavelength division multiplexing mode.

24. The system of claim 15, wherein the optical fiber is operated using Rayleigh scattering.

25. A method of detecting and localizing a partial discharge in a power transformer, the method comprising:
a) providing the system of claim 1, for detection of a partial discharge in a power transformer;
b) triggering the fiber optic acoustic sensor to gather acoustic data from the partial discharge;
c) transmitting the acoustic data to the data acquisition module; and
calculating the location of the partial discharge within the power transformer.
